(19) United States
(12) Patent Application Publication
(10) Pub. No.: US 2024/0003944 A1
(43) Pub. Date: Jan. 4, 2024

(54) ELECTRONIC DEVICE AND DETECTION METHOD THEREOF

(71) Applicants: InnoLux Corporation, Miao-Li County (TW); CARUX TECHNOLOGY PTE. LTD., SINGAPORE (SG)

(72) Inventors: Chia-Min YEH, Miao-Li County (TW); Hsieh-Li CHOU, Miao-Li County (TW); Cheng-Tso CHEN, Miao-Li County (TW); Yi-Cheng CHANG, Miao-Li County (TW)

(21) Appl. No.: 18/327,277

(22) Filed: Jun. 1, 2023

Related U.S. Application Data
(60) Provisional application No. 63/367,624, filed on Jul. 4, 2022.

(30) Foreign Application Priority Data
Mar. 13, 2023 (CN) 202310236167.7

(51) Int. Cl. G01R 19/25; G01R 19/165

(52) U.S. Cl. CPC G01R 19/2506; G01R 19/16566

(57) ABSTRACT

An electronic device is provided. The electronic device includes a panel, a detection system, and a test loop. The test loop is electrically connected to the panel and the detection system. The detection system includes a detection unit and a controller. The detection unit detects a signal transmitted by the test loop, and provides a detection result to the controller.

### CROSS REFERENCE TO RELATED APPLICATIONS

This application claims the benefit of U.S. Provisional Application No. 63/367,624, filed on Jul. 4, 2022, and China Application No. 202310236167.7, filed on Mar. 13, 2023, the entirety of which is incorporated by reference herein.

### BACKGROUND OF THE DISCLOSURE

### Field of the Invention

The present invention relates to an electronic device, and, in particular, to an electronic device and a method for detecting bonding states.

### Description of the Related Art

In the prior art, the bonding state can be roughly judged after the bonding process by observing the indentation or fracture pattern of the conductive particles, but the bonding resistance cannot be judged.

In product applications, some factors (such as vibration and temperature) can lead to bonding degradation, and this bonding degradation cannot be detected in advance. Therefore, how to detect bonding resistance in real time has become an important issue.

### BRIEF SUMMARY OF THE DISCLOSURE

An embodiment of the present disclosure provides an electronic device. The electronic device includes a panel, a detection system, and a test loop. The test loop is electrically connected to the panel and the detection system. The detection system includes a detection unit and a controller. The detection unit detects a signal transmitted by the test loop, and provides a detection result to the controller.

An embodiment of the present disclosure also provides an electronic device. The electronic device includes a panel, a vehicle detection system, and a test loop. The test loop is electrically connected to the panel and the vehicle detection system. The vehicle detection system includes a detection unit and a controller. The detection unit detects a signal transmitted by the test loop, and provides a detection result to the controller.

An embodiment of the present disclosure also provides a detection method for an electronic device. The electronic device includes a panel, a detection system, and a test loop. The test loop is electrically connected to the panel and the detection system. The detection system includes a detection unit and a controller. The detection method includes the following stage. A signal is applied to the test loop. The detection unit receives the signal through the test loop. The detection unit detects the signal transmitted through the test loop, and provides a detection result to the controller.

### BRIEF DESCRIPTION OF THE DRAWINGS

The disclosure can be more fully understood by reading the subsequent detailed description with references made to the accompanying figures. It should be understood that the figures are not drawn to scale in accordance with standard practice in the industry. In fact, it is allowed to arbitrarily enlarge or reduce the size of components for clear illustration. This means that many special details, relationships and methods are disclosed to provide a complete understanding of the disclosure.

FIG. 1 is a schematic diagram of an electronic device 100 in accordance with some embodiments of the present disclosure.

FIG. 2 is a schematic diagram of the partial electronic device 100 in accordance with some embodiments of the present disclosure.

FIG. 3 is a component connection diagram of the electronic device 100 in accordance with some embodiments of the present disclosure.

FIG. 4 is a schematic diagram of a partial electronic device 400 in accordance with some embodiments of the present disclosure.

FIG. 5 is a schematic diagram of the partial electronic device 400 in accordance with some embodiments of the present disclosure.

FIG. 6 is a schematic diagram of the partial electronic device 400 in accordance with some embodiments of the present disclosure.

FIG. 7 is a schematic diagram of a partial electronic device 700 in accordance with some embodiments of the present disclosure.

FIG. 8 is a schematic diagram of the partial electronic device 700 in accordance with some embodiments of the present disclosure.

FIG. 9 is a schematic diagram of a partial electronic device 900 in accordance with some embodiments of the present disclosure.

FIG. 10 is a schematic diagram of the partial electronic device 900 in accordance with some embodiments of the present disclosure.

FIG. 11 is a connection block diagram of an electronic device 1100 in accordance with some embodiments of the present disclosure.

FIG. 12 is a connection block diagram of an electronic device 1200 in accordance with some embodiments of the present disclosure.

FIG. 13 is a flow chart of a detection method for an electronic device in accordance with some embodiments of the present disclosure.

FIG. 14 is a flow chart of the step S1304 in the detection method in FIG. 13 in accordance with some embodiments of the present disclosure.

### DETAILED DESCRIPTION OF THE DISCLOSURE

In order to make the above purposes, features, and advantages of some embodiments of the present disclosure more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present disclosure are used to indicate the existence of specific technical features, values, method steps, operations, units and/or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without departing from the spirit of the present disclosure.

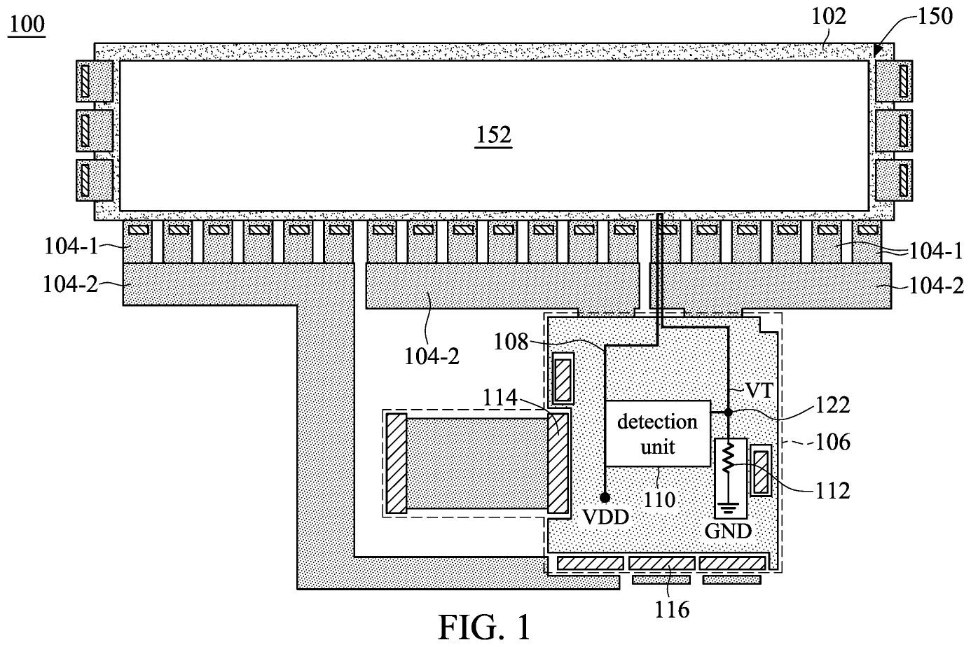

In the present disclosure, the electronic device in FIG. 1 in the present disclosure may include a display device, a backlight device, an antenna device, a sensing device, or a splicing device, etc., but is not limited thereto. The electronic device may be a bendable or flexible electronic device. The display device may be a non-self-luminous display device or a self-luminous display device. The antenna device may be a liquid crystal antenna device or a non-liquid crystal antenna device, and the sensing device may be a sensing device for sensing capacitance, light, heat, or ultrasonic waves, but is not limited thereto. The electronic components may include passive and active components, such as capacitors, resistors, inductors, diodes, transistors, and the like. The diodes may include light-emitting diodes or photodiodes. The light-emitting diode may include organic light-emitting diode (OLED), inorganic light-emitting diode, micro-LED, mini-LED, quantum dot light-emitting diode (QLED, QDLED), other suitable materials or a combination of the above materials, but is not limited thereto. The splicing device may be, for example, a splicing display device or a splicing antenna device, but is not limited thereto. In addition, the display device in the electronic device may be a color display device or a monochrome display device, and the shape of the electronic device may be rectangular, circular, polygonal, a shape with curved edges, or other suitable shapes. In addition, the electronic device described below uses, as an example, the sensing of a touch through an embedded touch device, but the touch-sensing method is not limited thereto, and another suitable touch-sensing method can be used provided that it meets all requirements.

FIG. 1 is a schematic diagram of an electronic device 100 in accordance with some embodiments of the present disclosure. As shown in FIG. 1, the electronic device 100 includes a panel 102, at least one first circuit board 104-1 bonded to the panel 102, at least one circuit board 104-2 bonded to the first circuit board 104-1, and at least one second circuit board 106. In some embodiments, the at least one second circuit board 106 is electrically connected to the panel 102 through the at least one circuit board 104-2 and the at least one circuit board 104-1, for example. In other words, the first circuit board 104-1 may be electrically connected between the at least one circuit board 104-2 and the panel 102. The at least one circuit board 104-2 may be electrically connected between the at least one first circuit board 104-1 and the second circuit board 106, but the present disclosure is not limited thereto. In some embodiments, the panel 102 includes an active area (AA) 152 and a non-active area 150. The panel 102 may include, for example, a display panel, a touch panel, a detection panel or other suitable panels, but the present disclosure is not limited thereto. The active area may include, for example, a display area, a touch area, a detection area, or other areas with suitable functions. In some embodiments, the second circuit board 106 is electrically connected to the circuit board 104-2 through the connector 116. The second circuit board 106 is electrically connected to other external circuit boards (not shown) through the connector 114. In some embodiments, the at least one first circuit board 104-1 includes chip-on-film (COF), but the present disclosure is not limited thereto. In some embodiments, the at least one circuit board 104-2 includes a flexible printed circuit (FPC), but the present disclosure is not limited thereto.

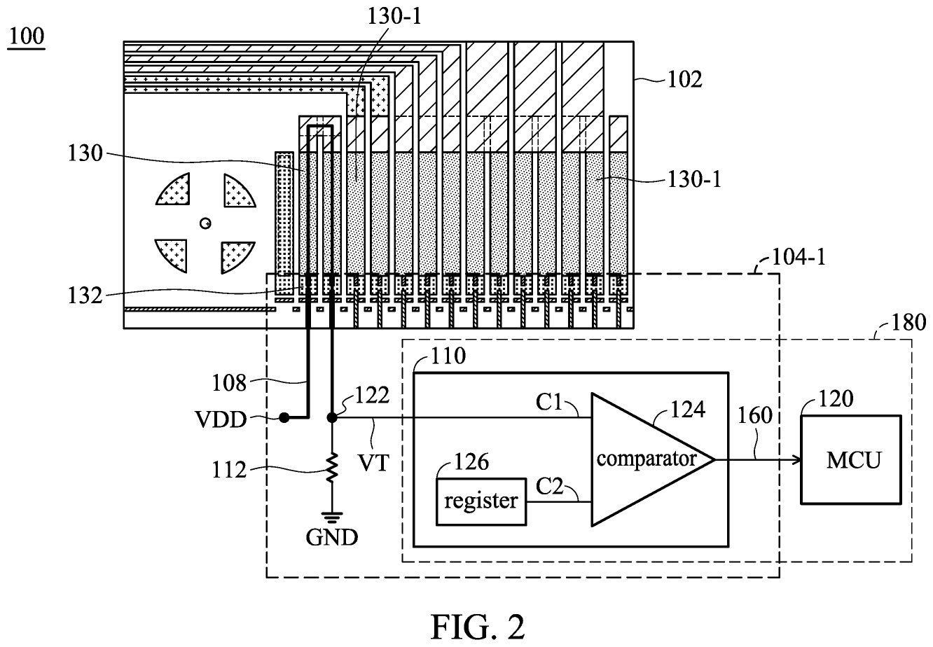

In some embodiments, the second circuit board 106 includes, for example, a printed circuit board (PCB), but the present disclosure is not limited thereto. In some embodiments, the detection unit 110 and/or the external resistor 112 is, for example, disposed on the second circuit board 106. In some embodiments, the detection system 180 (as shown in FIG. 2, for example, the vehicle detection system, but is not limited thereto) includes detection unit 110 and the controller 120 (as shown in FIG. 2). The test loop 108 is electrically connected the panel 102 and the detection system 180. In other words, the detection system 180 is electrically connected the panel 102 through the test loop 108. In some embodiments, the detection unit 110 detects a signal transmitted by the test loop 108, and provides a detection result to the controller 120. In detail, one end of the test loop 108 is electrically connected to a power-supply voltage VDD, the other end of the test loop 108 is electrically connected to a fixed voltage, for example, the ground voltage GND. The detection unit 110 is electrically connected to a node 122 (that is, at the detection voltage VT) of the test loop 108. An external resistor 112 is, for example, electrically connected between the node 122 and the fixed voltage (that is, the ground voltage GND) or the low voltage (not shown). The test unit 110 is, for example, electrically connected to the node 122 of the test loop 108, and the external resistor 112 is further electrically connected between the node 112 and the fixed voltage GND. In some embodiments, for example, according to the resistance value R_{ER} of the external resistor 112 and the resistance value R_{BD} of the equivalent resistance in the test loop 108, the voltage between the power-supply voltage VDD and the fixed voltage (i.e., the ground voltage GND) is divided to generate the detection voltage VT. The resistance value R_{BD} includes, for example, the bonding resistance between the second circuit board 106 and the circuit board 104-2, the bonding resistance between the circuit board 104-2 and the first circuit board 104-1, the bonding resistance between the first circuit board 104-1 and the panel 102, and/or the sum of the resistances of the lines in the test loop 108. The detection unit 110 is for example configured to receive the detection voltage VT. The formula of the above detection voltage VT is, for example, (VDD−GND)*[RER/(R_{ER}+R_{BD})])=VT.

The embodiment in FIG. 1 takes the test loop 108 as an example, but the number and connection path of the test loop are not limited.

FIG. 2 is a schematic diagram of the partial electronic device 100 in accordance with some embodiments of the present disclosure. As shown in FIG. 2, the panel 102 in the electronic device 100 (for example, the non-active area 150 in FIG. 1) includes a first dummy pad 130 and multiple first conductive pads 130-1. For example, the multiple first conductive pads 130-1 are respectively electrically connected to multiple data lines (not shown) or multiple scan lines (not shown). In some embodiments, the first dummy pad 130 is, for example, adjacent to at least one of the multiple first conductive pads 130-1, and is electrically insulated from the multiple first conductive pads 130-1. The first dummy pad 130 is, for example, disposed outside the multiple first conductive pads 130-1, but the present disclosure is not limited thereto. In some embodiments, the first circuit board 104-1 includes a second dummy pad 132 and multiple second conductive pads 130-2. The multiple second conductive pads 130-2 are respectively electrically connected or bonded to the multiple first conductive pads 130-1. The second dummy pad 132 is electrically connected or bonded to the first dummy pad 130. In some embodiments, the second dummy pad 132 is, for example, adjacent to at least one of the multiple second conductive pads 130-2, and is electrically insulated from the multiple second conductive pads 130-2. The second dummy pads 132 are, for example, disposed outside the multiple second conductive pads 130-2, but the present disclosure is not limited thereto.

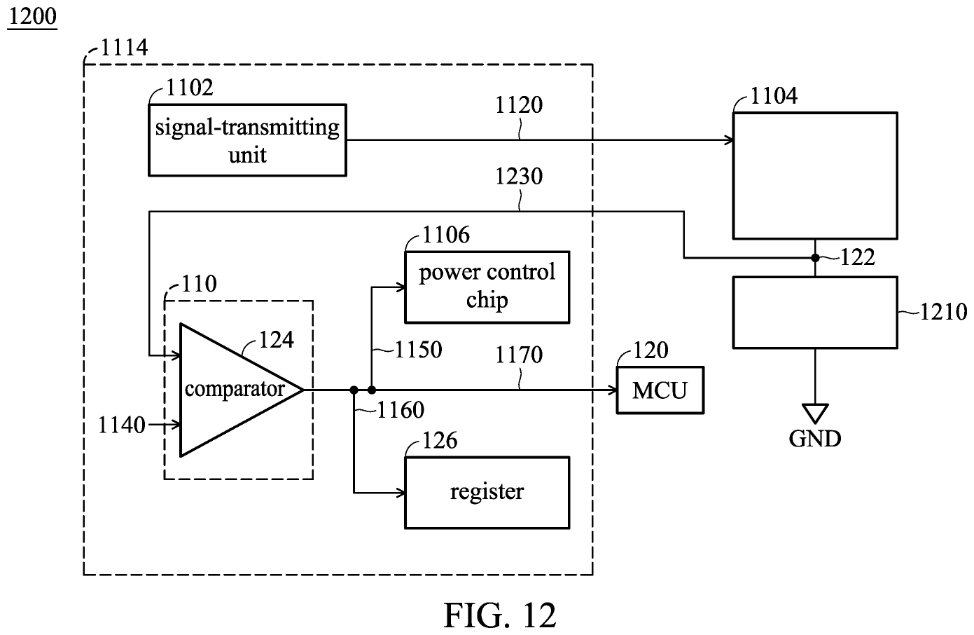

In some embodiments, the first dummy pad 130 is, for example, electrically connected to the detection system 180 through the test loop 108. In some embodiments, the detection system 180 can be a vehicle detection system or a detection system of other carrier, but the present disclosure is not limited thereto. The detection system 180 includes detection unit 110 and the controller (MCU) 120. The detection unit 110 detects a signal transmitted by the test loop 108, and provides a detection result 160 to the controller 120. In some embodiments, the controller 120 includes a microcontroller, but the present disclosure is not limited thereto. In some embodiments of FIG. 2, the detection unit 110 is, for example, disposed on the second circuit board 106, but the present disclosure is not limited thereto. In some embodiments, the detection unit 110 includes a comparator 124 and/or a register 126. A first end C1 of the comparator 124 is, for example, electrically connected to the node 122 for receiving the signal transmitted by the test loop 108, and a second end C2 of the comparator 124 receives a setting signal. The setting signal may come from the register 126, and the setting signal may include a DC voltage value or a voltage range, but the present disclosure is not limited thereto. In some embodiments, the external resistor 112 is electrically connected between the node 122 and the ground voltage GND. In some embodiments, the comparator 124 compares the signal (for example, the detection voltage VT) and the setting signal to obtain the detection result 160. For example, when the detection result 160 is within the voltage range of the setting signal, the detection unit 110, for example, determines that the detection 160 is in a normal state, and the controller (MCU) 120 of the detection system 180, for example, can output a enable signal to a power control chip (not shown). The power control chip drives the panel 102 according to the enable signal. When the detection result 160 is that the voltage of the signal is not within the voltage range of the setting signal, the detection unit 110 may, for example, store the voltage data of the signal in the register 126 (refer to subsequent FIG. 12).

In some embodiments, the power control chip (not shown) is, for example, disposed on the first circuit board 104-1 or the panel 102, but the present disclosure is not limited thereto. It is noted that the above-mentioned voltage division formula of the detection voltage VT is, for example, (VDD−GND)*[RER/(R_{ER}+R_{BD})])=VT. It can be seen that the detection voltage VT is inversely proportional to the resistance value R_{BD}. In some embodiments, the setting signal is, for example, a voltage value. When the resistance value R_{BD} is normal (the resistance value R_{BD} is not abnormally increased), the detection voltage VT, for example, will not be lower than the voltage of the setting signal, that is, the detection result 160, for example, can be determined as a normal state of bonding. In some embodiments, when the resistance value R_{BD} is abnormal (R_{BD} is abnormally increased), the detection voltage VT is, for example, lower than the voltage of the setting signal. That is, the detection result 160 can determine an abnormal state, for example. When the detection unit 110 determines the abnormal state, the controller (MCU) 120 may not output the enable signal to the power control chip (not shown), so the power control chip does not control the panel 102 to be driven according to the enable signal. In some embodiments, after the controller 120 receives the detection result 160 from the detection unit 110, the controller 120 can output instructions correspondingly according to the detection result 160 to an external processor (not shown) for subsequent processing. In some embodiments, the external processor may include, for example, a vehicle control unit (VCU), but the present disclosure not limited thereto.

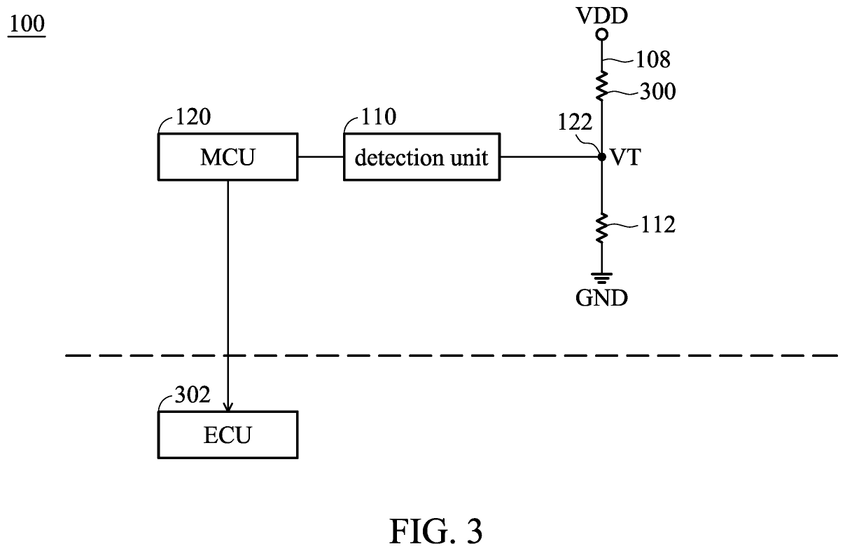

FIG. 3 is a component connection diagram of the electronic device 100 in accordance with some embodiments of the present disclosure. As shown in FIG. 3, the equivalent resistor 300 is, for example, electrically connected between the power-supply voltage VDD and the node 122. The external resistor 112 is, for example, electrically connected between the node 122 and the fixed voltage GND. For example, the detection unit 110 receives the detection voltage VT, compares the detection voltage VT with the voltage of the setting signal, and correspondingly outputs the detection result 160 to the controller 120, the detection and comparison method is as described above. If the detection result 160 is abnormal, the controller 120, for example, outputs an instruction to the electronic control unit (ECU) 302, so that the electronic control unit 302 can perform subsequent processing on the abnormality. In some embodiments, the electronic control unit 302 can be, for example, a vehicle (or carrier) control unit of a vehicle device (or carrier), but the present disclosure is not limited thereto.

For example, it is assumed that the power-supply voltage VDD is 3V, the equivalent resistance 300 is, for example, 5 ohms, and the external resistance is, for example, 5 ohms. Therefore, under normal conditions, the detection voltage VT on the node 122 is 1.5V. In some embodiments, if the bonding state of the panel 102 between the first circuit board 104-1 in FIG. 1, the bonding state between the circuit board 104-2 and the first circuit board 104-1 in FIG. 1, or the bonding state between the circuit board 104-1 and the second circuit board 106 in FIG. 1 is abnormal, for example, the resistance value R_{BD} of the equivalent resistor 300 increases abnormally (for example, larger than 5 ohms), which reduces the detection voltage VT (for example, lower than 1.5V). If the detection voltage VT is lower than the voltage of the setting signal (for example, 1.5V), the detection unit 110, for example, determines that it is in an abnormal state. After the controller 120 receives the detection result 160 (such as an abnormal state) from the detection unit 110, the controller 120 correspondingly outputs instructions to the electronic control unit 302, so that the electronic control unit 302 receives the abnormal state that has happened. In contrast, in some embodiments, if the detection voltage VT is not lower than the voltage of the setting signal, the detection unit 110 determines to be in a normal state, for example. The above-mentioned resistance value of the equivalent resistor 300, the resistance value of the external resistor 112, and the voltage value of the power-supply voltage VDD are only examples, and are not intended to be limitations of this disclosure. In other embodiments (not shown), other external resistors can be appropriately added according to other requirements.

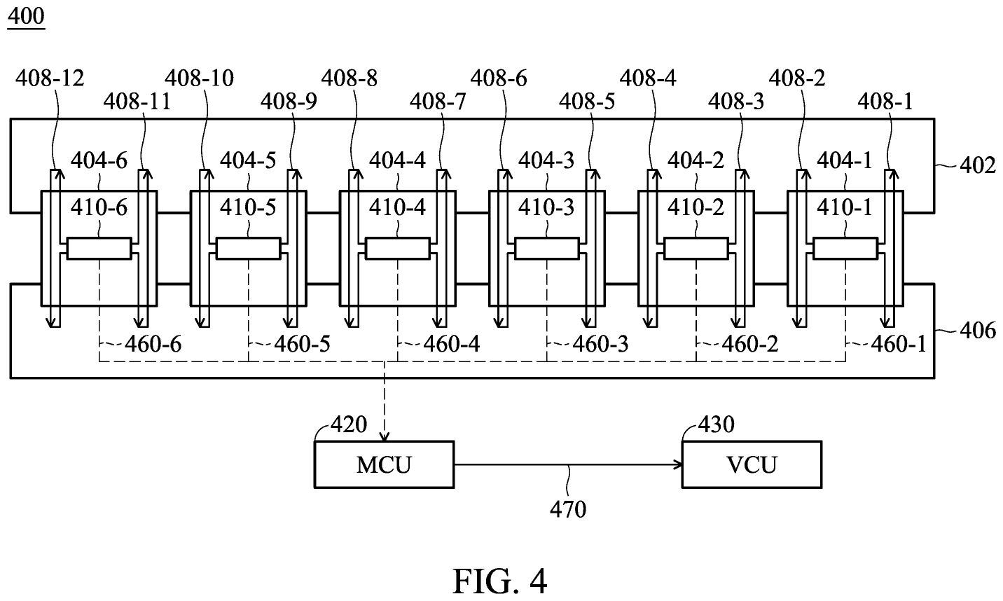

FIG. 4 is a schematic diagram of a partial electronic device 400 in accordance with some embodiments of the present disclosure. As shown in FIG. 4, the electronic device 400 includes a panel 402, multiple first circuit boards (such as the first circuit board 404-1 to the first circuit board 404-6), a second circuit board 406, and a controller (MCU) 420. The first circuit boards 404-1 to 404-6 may include chip-on-film (COF), but the present disclosure is not limited thereto. The second circuit board 406 includes a printed circuit board or a flexible circuit board, but the present disclosure is not limited thereto. In some embodiments, a data-driving chip 410-1 is disposed on the first circuit board 404-1. The data-driving chip 410-1 is electrically connected between the panel 402 and the second circuit board 406, for example, through the test loop 408-1 and/or the test loop 408-2. The data-driving chip 410-1, for example, detects a signal transmitted by the test loop 408-1 and/or the test loop 408-2, and provides the detection result 460-1 to the controller 420. In other words, the data-driving chip 410-1 can serve as the detection unit 110, for example, and the detection unit 110 is disposed on the first circuit board 404-1. Similarly, the first circuit board 404-2 includes a data-driving chip 410-2. The data-driving chip 410-2 is electrically connected between the panel 402 and the second circuit board 406 through the test loop 408-3 and/or the test loop 408-4. The data-driving chip 410-2 detects a signal transmitted by the test loop 408-3 and/or the test loop 408-4, and provides the detection result 460-2 to the controller 420. In other words, the data driver chip 410-2 can serve as a detection unit, for example. The first circuit board 404-3 includes a data-driving chip 410-3. The data-driving chip 410-3 is electrically connected between the panel 402 and the second circuit board 406 through the test loop 408-5 and/or the test loop 408-6. The data-driving chip 410-3 detects a signal transmitted by the test loop 408-5 and/or the test loop 408-6, and provides the detection result 460-3 to the controller 420. In other words, the data-driving chip 410-3 can serve as a detection unit, for example. The first circuit board 404-4 includes a data-driving chip 410-4. The data-driving chip 410-4 is electrically connected between the panel 402 and the second circuit board 406 through the test loop 408-7 and/or the test loop 408-8. The data-driving chip 410-4 detects a signal transmitted by the test loop 408-7 and/or the test loop 408-8, and provides the detection result 460-4 to the controller 420. In other words, the data-driving chip 410-4 can serve as a detection unit, for example. The first circuit board 404-5 includes a data-driving chip 410-5. The data-driving chip 410-5 is electrically connected between the panel 402 and the second circuit board 406 through the test loop 408-9 and/or the test loop 408-10. The data-driving chip 410-5 can be used to detect a signal transmitted by the test loop 408-9 and/or the test loop 408-10, and provides the detection result 460-5 to the controller 420. In other words, the data-driving chip 410-5 can serve as a detection unit, for example. The first circuit board 404-6 includes a data-driving chip 410-6. The data-driving chip 410-6 is electrically connected between the panel 402 and the second circuit board 406 through the test loop 408-11 and/or the test loop 408-12. The data-driving chip 410-6 detects a signal transmitted by the test loop 408-11 and the test loop 408-12, and provides the detection result 460-6 to the controller 420. In other words, the data-driving chip 410-6 can serve as a detection unit, for example.

In some embodiments, if the controller 420 finds that at least one of the detection result 460-1, the detection result 460-2, the detection result 460-3, the detection result 460-4, the detection result 460-5, and the detection result 460-6 is in the abnormal state, for example, the controller 420 sends an abnormal instruction 470 to the vehicle control unit (VCU) 430, and the vehicle control unit 430 can perform subsequent processing according to the abnormal instruction 470. The quantity of the above-mentioned first circuit boards and the quantity of the above-mentioned data-driving chips that can be used as detection units can be adjusted according to requirements. The number of test loops or the connection path of the test loops electrically connected to the data-driving chip are examples, and can be adjusted according to requirements.

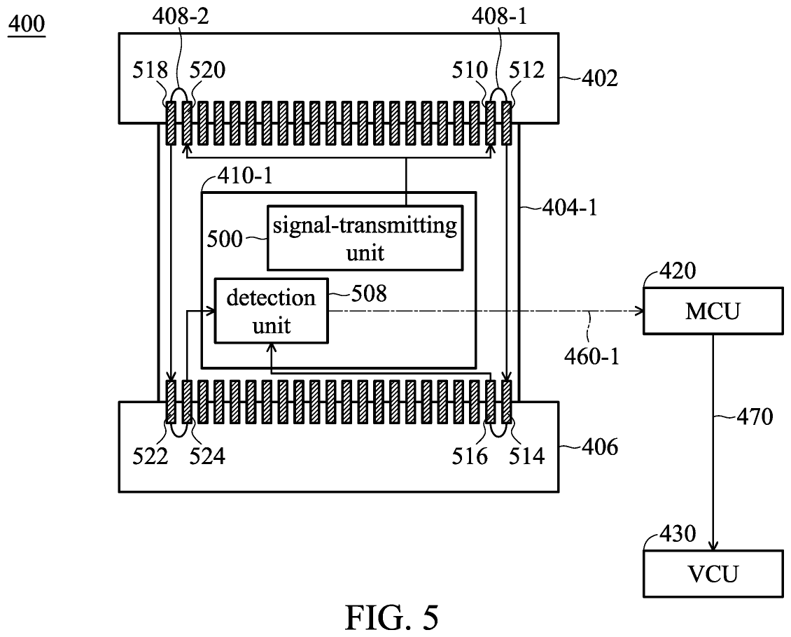

FIG. 5 is a schematic diagram of the partial electronic device 400 in accordance with some embodiments of the present disclosure. FIG. 5 takes the data-driving chip 410-1 in FIG. 4 as an example, other data-driving chips may have similar designs, but the present disclosure is not limited thereto. As shown in FIG. 5, the data-driving chip 410-1 is electrically connected to the panel 402 through, for example, the dummy pad set 510, the dummy pad set 512, the dummy pad set 518, and the dummy pad set 520. The aforementioned dummy pad sets (510, 512, 518, and 520) are formed by bonding, for example, the dummy pads on the panel 402 and the dummy pads on the first circuit board 404-1 with each other. Furthermore, the data-driving chip 410-1 is electrically connected to the second circuit board 406 through the dummy pad set 514, the dummy pad set 516, the dummy pad set 522, and the dummy pad set 524. The aforementioned dummy pad sets (514, 516, 522, and 524) are formed by bonding, for example, the dummy pads on the first circuit board 404-1 and the dummy pads on the second circuit board 406 with each other. In some embodiments, the data-driving chip 410-1 includes a signal-transmitting unit 500 and/or a detection unit 508. In other words, the data-driving chip 410-1 is electrically connected to the panel 402 and the second circuit board 406 through the test loop 408-1 and/or the test loop 408-2, for example. In the test loop 408-1, the signal-transmitting unit 500, for example, outputs a signal, and the signal is transmitted to the detection unit 508 through the dummy pad set 510, the dummy pad set 512, the dummy pad set 514 and/or the dummy pad set 516 in sequence, but the present disclosure is not limited to. Similarly, in the test loop 408-2, the signal-transmitting unit 500 outputs a signal, and the signal is transmitted to the detection unit 508 through the dummy pad set 520, the dummy pad set 518, the dummy pad set 522 and/or the dummy pad et 524 in sequence, but the present disclosure is not limited thereto. The detection unit 508 includes, for example, two sub-detection units (such as two comparators, but not limited thereto), respectively receiving the signals transmitted by the test loop 408-1 and the test loop 408-2, but the present disclosure is not limited thereto.

In some embodiments, the signal output by the signal-transmitting unit 500 may for example, include a DC voltage signal or a pulse voltage signal, but the present disclosure is not limited thereto. Afterwards, the detection unit 508 outputs the detection result 460-1 to the controller 420. The detection result 460-1 may include the detection results of the test loop 408-1 and/or the test loop 408-2. If the controller 420 finds that there is the abnormal state in the detection result 460-1, that is, the detection result of at least one of the test loop 408-1 and the test loop 408-2 has the abnormal state, the controller 420 (MCU), for example, sends the abnormal instruction 470 to the vehicle control unit (VCU) 430, so that the vehicle control unit 430 performs subsequent processing according to the abnormal instruction 470, but the present disclosure is not limited thereto.

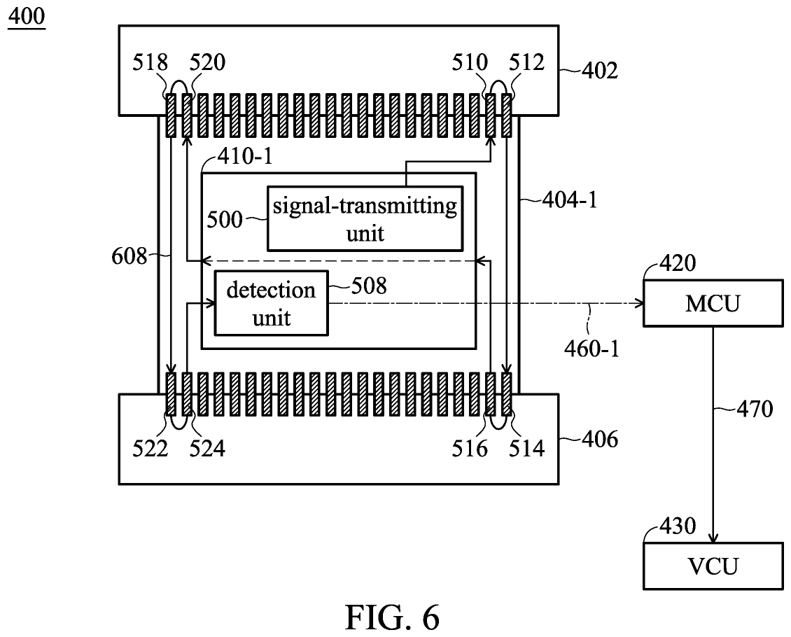

FIG. 6 is a schematic diagram of the partial electronic device 400 in accordance with some embodiments of the present disclosure. The difference between FIG. 6 and FIG. 5 is that the data-driving chip 410-1 is electrically connected to the panel 402 and the second circuit board 406, for example, through a single test loop 608. In detail, in the test loop 608, the signal-transmitting unit 500 outputs a signal. The signal is sent to the detection unit 508 through the dummy pad set 510, the dummy pad set 512, the dummy pad set 514, the dummy pad et 516, the internal circuit of the data-driving chip 410-1, the dummy pad set 520, the dummy pad set 518, the dummy pad set 522, and/or the dummy pad set 524. The detection unit 508 outputs the detection result 460-1 to the controller 420. The detection result 460-1 is the detection result of the test loop 608. The aforementioned dummy pad sets (510, 512, 518, and 520) are formed by bonding, for example, the dummy pads on the panel 402 and the dummy pads on the first circuit board 404-1 with each other. The aforementioned dummy pad sets (514, 516, 522, and 524) are formed by bonding, for example, the dummy pads on the first circuit board 404-1 and the dummy pads on the second circuit board 406 with each other. Similarly, if the controller 420 finds that there is the abnormal state in the detection result 460-1, that is, the detection result of the test loop 608 has the abnormal state, the controller 420 sends the abnormal instruction 470 to the vehicle control unit 430, so that the vehicle control unit 430 performs subsequent processing according to the abnormal instruction 470, but the present disclosure is not limited thereto.

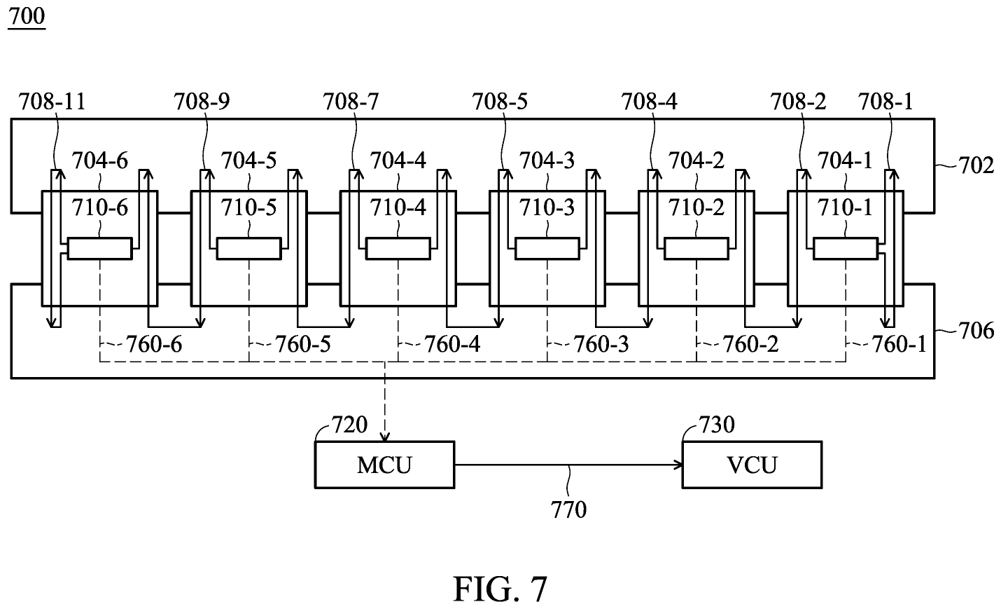

FIG. 7 is a schematic diagram of a partial electronic device 700 in accordance with some embodiments of the present disclosure. As shown in FIG. 7, the electronic device 700 includes a panel 702, multiple first circuit boards (704-1, 704-2, 704-3, 704-4, 704-5, and 704-6), a second circuit board 706, and/or a controller (MCU) 720, but the present disclosure is not limited thereto. The first circuit boards (704-1, 704-2, 704-3, 704-4, 704-5, and 704-6) may be chip-on-film (COF), but the present disclosure is not limited thereto. The second circuit board 706 is a printed circuit board, but the present disclosure is not limited thereto. In some embodiments, the first circuit board 704-1 includes a data-driving chip 710-1. The first circuit board 704-2 includes a data-driving chip 710-2. The first circuit board 704-3 includes a data-driving chip 710-3. The first circuit board 704-4 includes a data-driving chip 710-4. The first circuit board 704-5 includes a data-driving chip 710-5. The first circuit board 704-6 includes a data-driving chip 710-6.

In some embodiments, the data-driving chip 710-1 is electrically connected to the panel 702 and the second circuit board 706 through the test loop 708-1, and is electrically connected to the panel 702, the second circuit board 706 and the data-driving chip 710-2 through the test loop 708-2. The data-driving chip 710-1 detects the signal transmitted by the test loop 708-1, and provides the detection result 760-1 to the controller 720. The data-driving chip 710-2 is electrically connected to the panel 702 and the second circuit board 706 through the test loop 708-2, and is electrically connected to the panel 702, the second circuit board 706, and the data-driving chip 710-3 through the test loop 708-4. The data-driving chip 710-2 detects the signal transmitted by the test loop 708-2 and provides the detection result 760-2 to the controller 720.

The data-driving chip 710-3 is electrically connected to the panel 702, the second circuit board 706 and the data-driving chip 710-2 through the test loop 708-4, and is electrically connected to the panel 702, the second circuit board 706 and the data-driving chip 710-4 through the test loop 708-5. The data-driving chip 710-3 detects the signal transmitted by the test loop 708-4, and provides the detection result 760-3 to the controller 720. The data-driving chip 710-4 is electrically connected to the panel 702, the second circuit board 706 and the data-driving chip 710-3 through the test loop 708-5, and is electrically connected to the panel 702, the second circuit board 706 and the data-driving chip 710-5 through the test loop 708-7. The data-driving chip 710-4 detects the signal transmitted by the test loop 708-5 and provides the detection result 760-4 to the controller 720.

The data-driving chip 710-5 is electrically connected to the panel 702, the second circuit board 706 and the data-driving chip 710-4 through the test loop 708-7, and is electrically connected to the panel 702, the second circuit board 706 and the data-driving chip 710-6 through the test loop 708-9. The data-driving chip 710-5 detects the signal transmitted by the test loop 708-7, and provides the detection result 760-5 to the controller 720. The data-driving chip 710-6 is electrically connected to the panel 702, the second circuit board 706 and the data-driving chip 710-5 through the test loop 708-9, and is electrically connected to the panel 702 and the second circuit board 706 through the test loop 708-11. The data-driving chip 710-6 detects the signals transmitted by the test loop 708-9 and the test loop 708-11, and provides the detection result 760-6 to the controller 720. In some embodiments, if the controller 720 finds that at least one of the detection results 760-1, 760-2, 760-3, 760-4, 760-5, and 760-6 is in the abnormal state, the controller 420 sends an abnormal instruction 770 to the vehicle control unit (VCU) 730, so that the vehicle control unit 730 performs subsequent processing according to the abnormal instruction 770, but the present disclosure is not limited thereto.

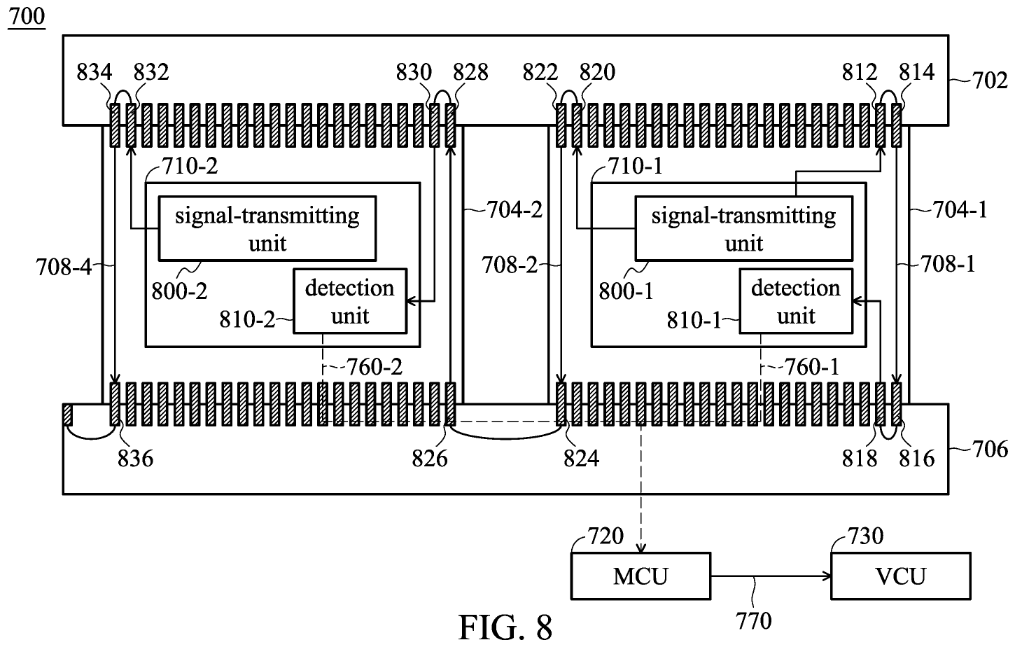

FIG. 8 is a schematic diagram of the partial electronic device 700 in accordance with some embodiments of the present disclosure. FIG. 8 takes the data-driving chip 710-1 and the data-driving chip 710-2 in FIG. 7 as an example. As shown in FIG. 8, the data-driving chip 710-1 is, for example, electrically connected to the panel 702 through the dummy pad set 812, the dummy pad set 814, the dummy pad set 820, and the dummy pad set 822. On the other hand, the data-driving chip 710-1 is, for example, electrically connected to the second circuit board 706 through the dummy pad set 816, the dummy pad set 818, and the dummy pad set 824. The aforementioned dummy pad sets (812, 814, 820 and 822) are formed by bonding, for example, the dummy pads on the panel 702 and the dummy pads on the first circuit board 704-1 with each other. The aforementioned dummy pad sets (816, 818, and 824) are formed by bonding, for example, the dummy pads on the first circuit board 704-1 and the dummy pads on the second circuit board 706 with each other.

In some embodiments, the data-driving chip 710-2 is, for example, electrically connected to the panel 702 through the dummy pad set 828, the dummy pad set 830, the dummy pad set 832, and the dummy pad set 834. On the other hand, the data-driving chip 710-2 is, for example, electrically connected to the second circuit board 706 through the dummy pad set 826 and the dummy pad set 836. The aforementioned dummy pad sets (828, 830, 832, and 834) are formed by bonding, for example, the dummy pads on the panel 702 and the dummy pads on the first circuit board 704-2 with each other. The aforementioned dummy pad sets (826 and 836) are formed by bonding, for example, the dummy pads on the first circuit board 704-2 and the dummy pads on the second circuit board 706 with each other. In some embodiments, the data-driving chip 710-1 includes, for example, a signal-transmitting unit 800-1 and/or a detection unit 810-1. The data-driving chip 710-2 includes a signal-transmitting unit 800-2 and/or a detecting unit 810-2.

In detail, in the test loop 708-1, the signal-transmitting unit 800-1 outputs a signal, for example, the signal passes through the dummy pad set 812, the dummy pad set 814, the dummy pad set 816, and the dummy pad set 818 in sequence, and is finally received by the detection unit 810-1. In some embodiments, the signal output by the signal-transmitting unit 800-1 includes a DC voltage signal or a pulse voltage signal, but the present disclosure is not limited thereto. Afterwards, the detection unit 810-1 outputs the detection result 760-1 to the controller 720. The detection result 760-1 includes the detection result for test loop 708-1. In the test loop 708-2, the signal-transmitting unit 800-1 outputs a signal, for example, the signal passes through the dummy pad set 820, the dummy pad set 822, the dummy pad set 824, the dummy pad set 826, the dummy pad set 828 and/or the dummy pad set 830, and is finally received by the detection unit 810-2. Afterwards, the detection unit 810-2 outputs the detection result 760-2 to the controller 720. The detection result 760-2 includes the test result for test loop 708-2. The connection path of the test loop 708-1 or the test loop 708-2 mentioned above is just an example, and can be adjusted according to requirements.

Similarly, in the test loop 708-4, the signal-transmitting unit 800-2 outputs a signal. For example, the signal passes through the dummy pad set 832, the dummy pad set 834 and/or the dummy pad set 836 in sequence, and is sent to the first circuit board 704-3 in FIG. 7 (not shown in FIG. 8) for subsequent testing done by the data-driving chip 710-3 in FIG. 7. In some embodiments, the signal output by the signal-transmitting unit 800-2 is a DC voltage signal or a pulse voltage signal, but the present disclosure is not limited thereto. Afterwards, the detection unit 810-2 outputs the detection result 760-2 to the controller 720. The detection result 760-2 includes the test result for test loop 708-2.

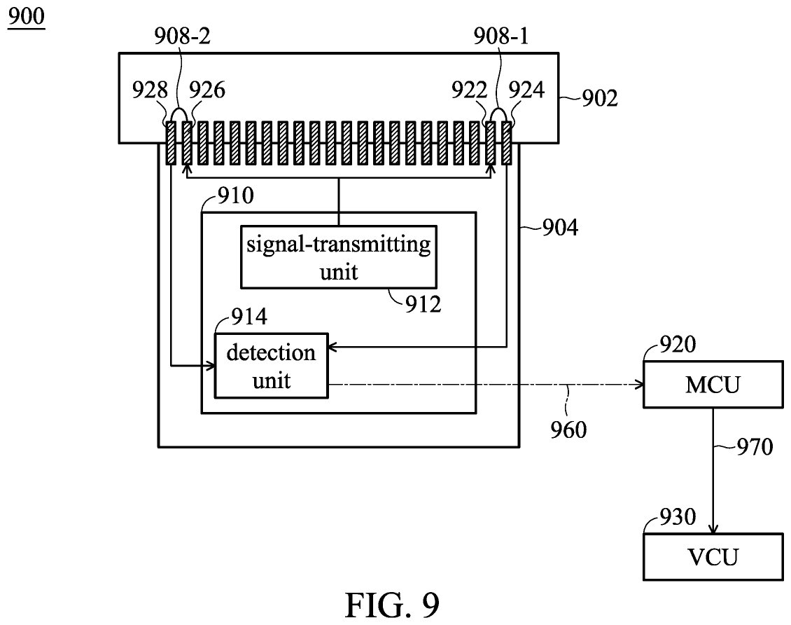

FIG. 9 is a schematic diagram of a partial electronic device 900 in accordance with some embodiments of the present disclosure. As shown in FIG. 9, the electronic device 900 includes a panel 902, a first circuit board 904, and/or a controller (MCU) 920. As shown in FIG. 9, the first circuit board 904 is, for example, electrically connected to the panel 902 through the dummy pad set 922, the dummy pad set 924, the dummy pad set 926, and the dummy pad set 928. The data-driving chip 910 is, for example, disposed on the first circuit board 904. The aforementioned dummy pad sets (922, 924, 926, and 928) are formed by bonding, for example, the dummy pads on the panel 902 and the dummy pads on the first circuit board 904 with each other. The data-driving chip 910 is, for example, electrically connected to the panel 902 through the test loop 908-1 and/or the test loop 908-2. In some embodiments, the data-driving chip 910 includes a signal-transmitting unit 912 and/or a detection unit 914.

In detail, in the test loop 908-1, the signal-transmitting unit 912 outputs a signal. For example, the signal is transmitted to the detection unit 914 through the dummy pad set 922 and the dummy pad set 924 in sequence. On the other hand, in the test loop 908-2, the signal-transmitting unit 912 outputs a signal. For example, the signal passes through the dummy pad set 926 and the dummy pad set 928 in sequence and then is transmitted to the detection unit 914. Afterwards, the detection unit 914 outputs a detection result 960 to the controller 920. The detection unit 914 includes, for example, two sub-detection units (such as two comparators, but not limited thereto), respectively receiving the signals transmitted by the test loop 908-1 and the test loop 908-2, but the present disclosure is not limited thereto. In some embodiments, the detection result 960 includes the detection result of the test loop 908-1 and/or the test loop 908-2. If the controller 920 finds that there is an abnormal state in the detection result 960, that is, the detection result of at least one of the test loop 908-1 and the test loop 908-2 has an error state, the controller 920 sends an abnormal instruction 970 to the vehicle control unit (VCU) 930, so that the vehicle control unit 930 performs subsequent processing according to the abnormal instruction 970.

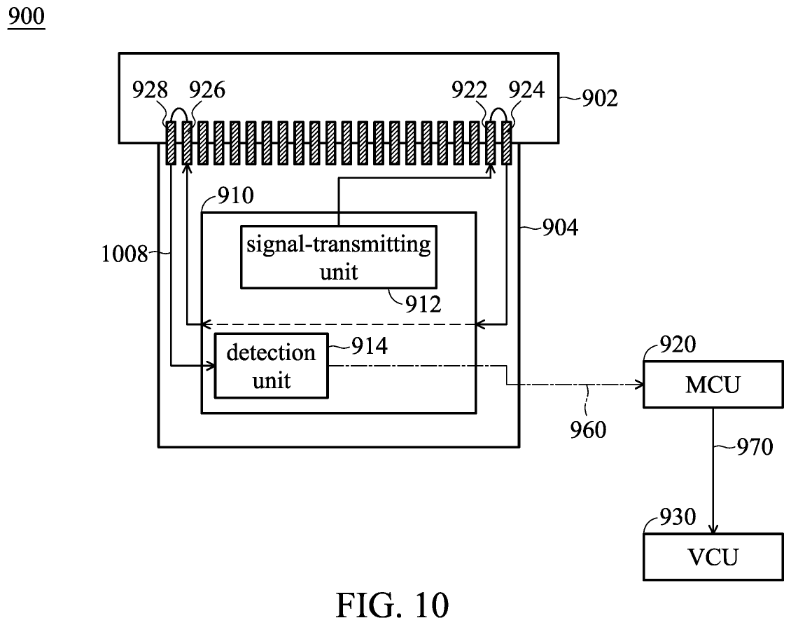

FIG. 10 is a schematic diagram of the partial electronic device 900 in accordance with some embodiments of the present disclosure. The difference between FIG. 10 and FIG. 9 is that the data-driving chip 910 is electrically connected to the panel 902 through a single test loop 1008. In detail, in the test loop 1008, the signal-transmitting unit 912 outputs a signal. For example, the signal is transmitted to the detection unit 914 through the dummy pad set 922, the dummy pad set 924, the internal circuit of the data-driving chip 910, the dummy pad set 926, and the dummy pad set 928. Afterwards, the detection unit 914 outputs the detection result 960 to the controller 920. The aforementioned dummy pad sets (922, 924, 926, and 928) are formed by bonding, for example, the dummy pads on the panel 902 and the dummy pads on the first circuit board 904 with each other. The detection result 960 is the detection result of the test loop 1008. If the controller 920 finds that there is an abnormal state in the detection result 960, that is, there is an abnormal state in the detection result of the test loop 1008, the controller 920 sends an abnormal instruction 970 to the vehicle control unit 930, so that the vehicle control unit 930 performs subsequent processing according to the abnormal instruction 970.

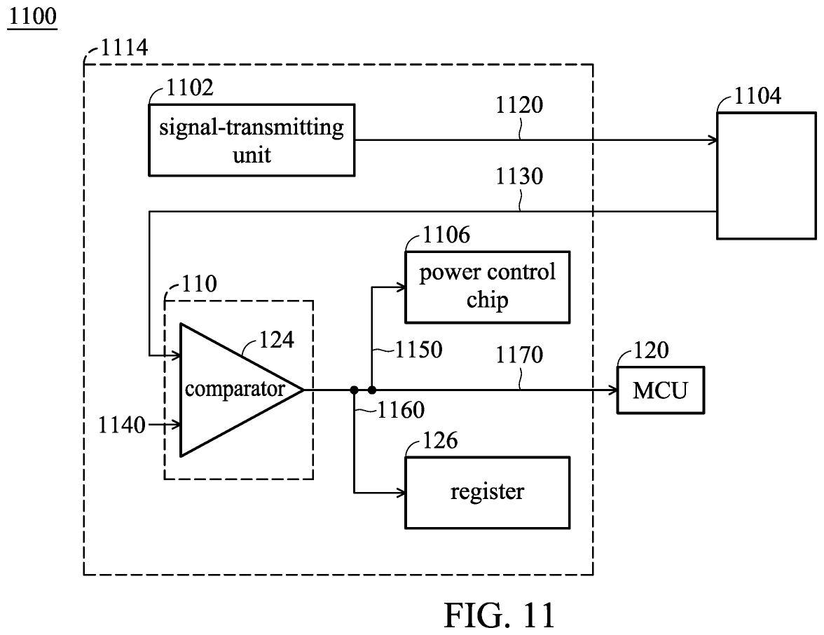

FIG. 11 is a connection block diagram of an electronic device 1100 in accordance with some embodiments of the present disclosure. As shown in FIG. 11, the electronic device 1100 includes a data-driving chip 1114, a total equivalent resistance 1104 (for example, including the bonding impedance of the panel and the first circuit board, the bonding impedance of the first circuit board and the second circuit board, and/or the bonding impedance of the circuit board and the second circuit board, but not limited thereto), and the controller (MCU) 120. In some embodiments, the data-driving chip 1114 is, for example, disposed on the first circuit board 104-1 in FIG. 1, but the present disclosure is not limited thereto. In some embodiments, the data-driving chip 1114 includes a signal-transmitting unit 1102, a detection unit 110, a power control chip 1106 and/or a register 126, but the present disclosure is not limited thereto. The detection unit 110 includes a comparator 124, but the present disclosure is not limited thereto. In some embodiments, the detection unit 110 includes other suitable detection elements.

In some embodiments, the signal-transmitting unit 1102 outputs a signal 1120. In some embodiments, when the detection unit 110 includes the comparator 124, the signal 1120 is, for example, a DC voltage signal, but the present disclosure is not limited thereto. In some embodiments, the signal 1120 is, for example, a pulse voltage signal. The signal 1120 passes through the voltage drop loss of the above-mentioned multiple bonding resistors to generate a signal 1130. The first end of the comparator 124 receives the above-mentioned signal 1130, for example, and the second end of the comparator 124 receives a setting signal 1140, for example. In some embodiments, the setting signal 1140 includes a single voltage value or a voltage range, and may come from the register 126, for example, but is the present disclosure is not limited thereto. The comparator 124 compares the signal 1130 and the setting signal 1140 to obtain a detection result 1170. For example, when the detection result 1170 is within the voltage range of the setting signal, the detection unit 110, for example, determines that the detection 1170 is in a normal state. The controller (MCU) 120 of the detection system 180, for example, outputs an enable signal to the power control chip 1106. The power control chip 1106 controls the driving of the panel 102 according to the enable signal, for example, but the present disclosure is not limited thereto. For example, in some embodiments, when the detection result 1170 is that the voltage of the signal 1130 is higher than the voltage of the setting signal 1140, for example, the detection result is normal, but the present disclosure is not limited thereto.

When the detection result 1170 is not within the voltage range of the setting signal, the detection unit 110, for example, determines that the detection 1170 is in an abnormal state. At this time, the controller (MCU) 120, for example, will not output an enable signal to the power control chip 1106, and the power control chip 110 will not drive the panel 102 according to the enable signal. In some embodiments, in some embodiments, when the detection result 1170 is that the voltage of the signal 1130 is lower than or equal to the voltage of the setting signal 1140, for example, the detection result is abnormal. In some embodiments, when the detection unit 110 determines that there is the abnormal state, for example, the voltage data of the detection voltage VT and/or the voltage data of the setting signal are stored in the register 126, but the present disclosure is not limited thereto. In other words, after the controller 120 receives the detection result 1170 from the detection unit 110, the controller 120 correspondingly outputs instructions to an external processor (not shown) for subsequent processing according to whether the detection result 1170 is normal or abnormal. In some embodiments, the external processor may include, for example, a vehicle control unit (VCU), but the present disclosure is not limited thereto.

FIG. 12 is a connection block diagram of an electronic device 1200 in accordance with some embodiments of the present disclosure. The difference between the electronic device 1200 in FIG. 12 and the electronic device 1100 in FIG. 11 is that the electronic device 1200 further includes an external resistor 1210 electrically connected between the node 122 (see FIG. 2) and the ground voltage GND, but the present disclosure is not limited thereto. Similarly, according to the external resistance 1210 and the total equivalent resistance 1104 (for example, including the bonding impedance of the panel and the first circuit board, the bonding impedance of the first circuit board and the second circuit board, and/or the bonding impedance of the circuit board and the second circuit board, but is not limited thereto), for example, the signal 1120 output by the signal-transmitting unit 1102 is divided to generate the signal 1230. The first end of the comparator 124 receives the signal 1230, and the second end of the comparator 124 receives the setting signal 1140. The signal 1230 is compared with the setting signal 1140 through the comparator 124 to obtain a detection result 1170. Next, the detection unit 110 for example, outputs the detection result 1170 to the controller 120. The process of generating the detection result 1170 by the detection unit 110 in FIG. 12 is substantially the same as that in FIG. 11, so it will not be repeated here.

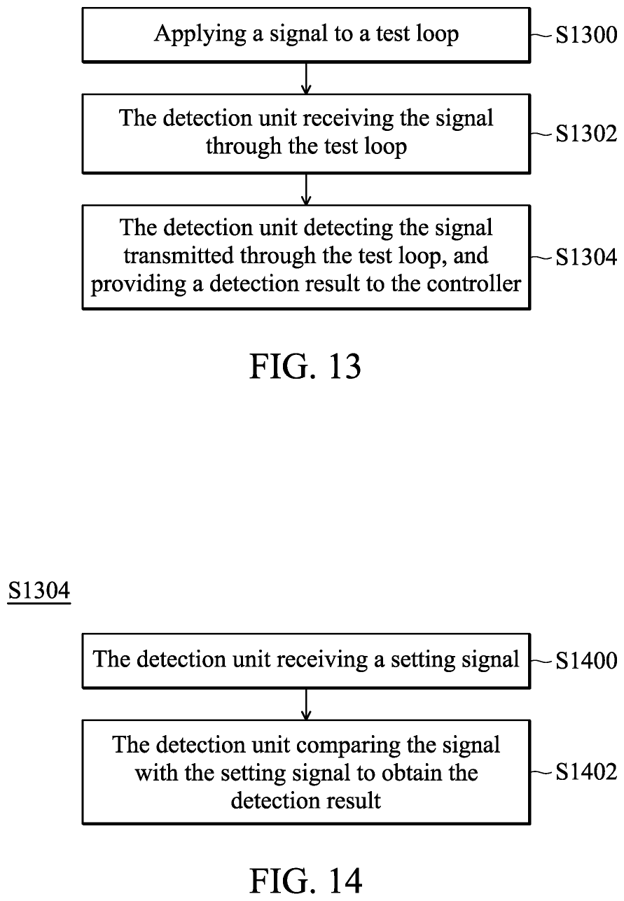

FIG. 13 is a flow chart of a detection method for an electronic device in accordance with some embodiments of the present disclosure. The detection method disclosed in the present disclosure is applicable to the electronic device 100 in FIGS. 1 to 3, the electronic device 400 in FIGS. 4 to 6, the electronic device 700 in FIGS. 7 and 8, the electronic device 900 in FIGS. 9 and 10, the electronic device 1100 in FIG. 11, and the electronic device 1200 in FIG. 12. As shown in FIG. 13, the detection method of the present disclosure includes the following stages. A signal is applied to the test loop (step S1300). The detection unit receives the signal through the test loop (step S1302). The detection unit detects the signal transmitted through the test loop, and provides a detection result to the controller (step S1304). FIG. 14 is a flow chart of the step S1304 in the detection method in FIG. 13 in accordance with some embodiments of the present disclosure. As shown in FIG. 14, step S1304 of FIG. 13 includes the following stages. The detection unit receives a setting signal (step S1400). The detection unit compares the signal with the setting signal to obtain the detection result (step S1402). When the detection result indicates that the voltage of the signal is within the voltage range of the setting signal, the detection unit outputs an enable signal to drive the panel. When the detection result indicates that the signal is abnormal, the detection unit stores the voltage data of the signal and the voltage data of the setting signal in a register.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a panel;
a detection system; and
a test loop, electrically connected to the panel and the detection system;
wherein the detection system comprises a detection unit and a controller and the detection unit is configured to detect a signal transmitted by the test loop, and provide a detection result to the controller.

2. The electronic device as claimed in claim 1, wherein the detection unit comprises a comparator, a first end of the comparator receives the signal transmitted by the test loop, a second end of the comparator receives a setting signal, and the comparator compares the signal with the setting signal to obtain the detection result.

3. The electronic device as claimed in claim 1, further comprising a first circuit board, wherein the first circuit board is bonded to the panel, and the detection unit is disposed on the first circuit board.

4. The electronic device as claimed in claim 1, further comprising a first circuit board and a second circuit board; wherein the first circuit board is bonded to the panel, the second circuit board is electrically connected to the panel through the first circuit board, and the detection unit is disposed on the second circuit board.

5. The electronic device as claimed in claim 1, further comprising a first circuit board bonded to the panel; wherein the panel comprises a first dummy pad, the first circuit board comprises a second dummy pad bonded to the first dummy pad, and the first dummy pad is electrically connected to the detection system through the test loop.

6. The electronic device as claimed in claim 1, wherein one end of the test loop is electrically connected to a power-supply voltage, the other end of the test loop is electrically connected to a fixed voltage, the detection unit is electrically connected to a node of the test loop, and an external resistor is electrically connected between the node and the fixed voltage.

7. The electronic device as claimed in claim 2, wherein the controller outputs an enable signal when the detection result is within the voltage range of the setting signal.

8. The electronic device as claimed in claim 7, further comprising:
a power control chip, configured to receive the enable signal and control the driving of the panel according to the enable signal.

9. An electronic device, comprising:
a panel;
a vehicle detection system;
a test loop, electrically connected to the panel and the vehicle detection system;
wherein the vehicle detection system comprises a detection unit and a controller; and the detection unit is configured to detect a signal transmitted by the test loop, and provide a detection result to the controller.

10. The electronic device as claimed in claim 9, wherein the detection unit comprises a comparator, the first end of the comparator receives the signal transmitted by the test loop, the second end of the comparator receives a setting signal, and the comparator compares the signal with the setting signal to obtain the detection result.

11. The electronic device as claimed in claim 9, further comprising a first circuit board, wherein the first circuit board is bonded to the panel, and the detection unit is disposed on the first circuit board.

12. The electronic device as claimed in claim 9, further comprising a first circuit board and a second circuit board; wherein the first circuit board is bonded to the panel, the second circuit board is electrically connected to the panel through the first circuit board, and the detection unit is disposed on the second circuit board.

13. The electronic device as claimed in claim 9, further comprising a first circuit board bonded to the panel; wherein the panel comprises a first dummy pad, the first circuit board comprises a second dummy pad bonded to the first dummy pad, and the first dummy pad is electrically connected to the detection system through the test loop.

14. The electronic device as claimed in claim 9, wherein one end of the test loop is electrically connected to a power-supply voltage, the other end of the test loop is electrically connected to a fixed voltage, the detection unit is electrically connected to a node of the test loop, and an external resistor is electrically connected between the node and the fixed voltage.

15. The electronic device as claimed in claim 10, wherein the controller outputs an enable signal when the detection result is within the voltage range of the setting signal.

16. The electronic device as claimed in claim 15,
a power control chip, configured to receive the enable signal and control the driving of the panel according to the enable signal.

17. A detection method for an electronic device, wherein the electronic device comprises a panel, a detection system, and a test loop; the test loop is electrically connected to the panel and the detection system, and the detection system comprises a detection unit and a controller; wherein the detection method comprises:
applying a signal to the test loop;
the detection unit receives the signal through the test loop; and
the detection unit detects the signal transmitted through the test loop, and provides a detection result to the controller.

18. The detection method as claimed in claim 17, further comprising:
the detection unit receives a setting signal; and
the detection unit compares the signal with the setting signal to obtain the detection result.

19. The detection method as claimed in claim 17, further comprising:
the detection unit outputs an enable signal to drive the panel when the detection result indicates that the voltage of the signal is within the voltage range of the setting signal; and

20. The detection method as claimed in claim 17, further comprising:
the voltage data of the signal and the voltage data of the setting signal are stored in a register when the detection result indicates that the signal is abnormal.
